(19) United States
(12) Patent Application Publication
(10) Pub. No.: US 2021/0020474 A1
(43) Pub. Date: Jan. 21, 2021

(54) AUTOMATIC OUTPUT REEL CHANGER

(71) Applicant: Grand Team Technologies Limited, Singapore (SG)

(72) Inventors: Lee Huat NG, Singapore (SG); Prem HAIR SEGARAN, Masai, Johor (MY)

(21) Appl. No.: 16/980,153

(22) PCT Filed: Mar. 15, 2019
(86) PCT No.: PCT/SG2019/050144

§ 371 Date: Sep. 11, 2020

(30) Foreign Application Priority Data
Mar. 15, 2018 (SG) 10201802147W

(51) Int. Cl. H01L 21/67; H05K 13/02; H05K 13/04

(52) U.S. Cl. CPC H01L 21/67132; H05K 13/0419; H05K 13/021

(57) ABSTRACT

The application provides an improved automated reel changer for a tape and reel machine. The automated reel changer includes an input reel station, a first elevator holder module, a spooler module, a tape insertion module, a movable second elevator holder module, an output reel station, and a control unit.

The application relates to a tape reel handling apparatus for a tape and reel machine. In particular, the application relates to a tape reel handling apparatus for loading a plurality of tape reels onto a tape and reel machine, wherein the tape reel is used for receiving a flexible tape that carries electronic components, such as semiconductor devices.

The tape and reel machine acts to transfer electronic components, such as semiconductor die or packaged integrated circuit chips, onto pockets of a flexible linear tape. A cover tape is then attached to the pockets of the flexible linear tape for sealing the pockets such that the electronic components are trapped in the pockets and that they do not leave the pockets.

After this, the tape and reel machine provide the flexible linear tape to a tape reel, wherein the tape reel is spun while the flexible linear tape is circumferentially wound around the tape reel.

When a predetermined length of the flexible linear tape is wound around the tape reel, the tape reel is considered as full. This tape reel is then replaced with an empty tape reel, thereby allowing remaining flexible linear tape with electronic components to be wound around the replaced tape reel.

US20110220755 discloses a device for automatic coiling and/or uncoiling on reels of a flexible tape carrier of electronic components. The device includes a coiling location where a reel can be connected to a rotation actuator, and retractable tape guides, which includes articulated jaws that can be closed together to form a channel for guiding the flexible tape and to connect a free end of the flexible tape to a hub of the reel. The device further includes a stopper element that engages with a slot in the reel hub, in order to stop the reel in a position in which the slot is aligned with the tape guide.

WO02099726A2 shows a multiple output reel module (MROM) for use with a taper machine or any other machine that outputs flexible media. The MROM includes an upper spindle shaft supporting a plurality of output reels, a lower spindle shaft supporting a plurality of output reels, and a tape insertion assembly that positions the flexible media adjacent to a hub of one of the output reels along a loading plane. The MROM further includes a finger assembly that holds the flexible media against the hub, a cutting assembly for cutting the flexible media, and a reel moving mechanism operable to move the output reels into and out of alignment with the loading plane. The MROM also includes a reel support structure along which the upper and lower spindle shafts are moveable in a linear direction. The flexible media may be held against the hub of the output reels with a finger assembly or a length of adhesive tape. Adhesive tape may also be used to secure the tail end of the flexible media against the last layer of flexible media that is wound onto a full reel.

It is an objective of the application to provide an improved automated output reel changer for automatically changing tape reels.

The application provides an automated reel changer for a tape and reel machine.

The tape-and-reel machine is used for placing objects into pockets of a flexible carrier tape. An example of the object is an electronic component, which can refer to a semiconductor die or to a packaged integrated circuit chip. The tape-and-reel machine also acts to place a cover tape onto the carrier tape such that objects remain with the carrier tape. In other words, the cover tape serves to trap the objects.

The automated reel changer acts to receive a plurality of tape reels. The automated reel changer also receives a carrier tape from the tape-and-reel machine, wherein the automated reel changer guides the carrier tape for coiling around a hub of the tape reel to form a coiled tape reel.

The automated reel changer includes an input reel station, a movable first elevator holder module, a movable spooler module, a tape insertion module, a movable second elevator holder module, an output reel station, and a control unit.

The input reel station is used for receiving and storing a plurality of empty tape reels. In other words, tapes are not wound around the tape reels.

The first elevator holder module is configured for moving essentially in the vertical direction. The first elevator holder module is used for receiving the plurality of empty tape reels, one tape reel at a time, from the input reel station.

The first elevator holder module then moves the received empty tape reels essentially downwards in the vertical direction to an elevator reel work position.

The spooler module is adapted for moving essentially in the horizontal direction. The spooler module is used for receiving the empty tape reel at the elevator reel work position from the first elevator holder module.

The tape insertion module is provided for receiving a moving carrier tape from the tape and reel machine and for guiding the received moving carrier tape.

The spooler module is also provided for positioning the empty tape reel to receive the moving carrier tape from the tape and reel machine, and for coiling the moving carrier tape around a hub of the tape reel to form a coiled tape reel.

The second elevator holder module is adapted for moving essentially in the vertical direction. The second elevator holder module is intended for receiving the coiled tape reel, at the elevator reel work position, from the spooler module. The second elevator holder module then moves the coiled tape reel downwards essentially, in the vertical direction, to an elevator reel unloading position.

The output reel station then receives the coiled tape reel, at the elevator reel unloading position, from the second elevator holder module.

The control unit is adapted to direct movement of the first elevator holder module, movement of the spooler module, movement of the tape insertion module, and movement of the second elevator holder module.

The automated reel changer provides a benefit in that it can receive multiple tape reels without operator support or intervention. In other words, the automated reel changer acts to save labor cost.

The automated reel changer can include a sticker module for placing a sticker onto an end portion of the carrier tape that is provided for coiling around the hub of the tape reel.

The automated reel changer can also include a bar code scanner for retrieving information from a bar code label of the tape reel regarding the tape reel. The information can relate to a data of the tape reel, such as width. The information can then be used to operate the automated reel changer.

The control unit can include a port for communicating with a computer server. The computer server can be provided by a computing cloud.

The automated reel changer can also include a roller arm module for pressing the moving carrier tape that is provided for coiling around the hub of the tape reel.

The application also provides a tape and reel unit. The tape-and-reel unit includes a tape and reel machine, the above-described automated reel changer, and an automated guided vehicle (AGV).

In use, the automated reel changer acts to receive a carrier tape from the tape and reel machine. The automated reel changer then coils the carrier tape around a hub of a tape reel to form a coiled tape reel.

The automated guided vehicle (AGV) is used for transporting the coiled tape reel from the automated reel changer to a predetermined location.

The automated guided vehicle can provide a safe and predictable method of delivering the tape reels, while avoiding interference with human and building factors. The automated guided vehicle can operate almost around the clock, without the need for breaks and vacation time.

The automated guided vehicle is often adapted for transporting a plurality of empty tape reels to the automated reel changer, wherein these tape reels are used for receiving the carrier tape.

The application also provides a tape and reel unit. The tape-and-reel unit includes a tape and reel machine, the above-described automated reel changer, and a computer server

The automated reel changer is used for receiving a carrier tape from the tape and reel machine and for coiling the carrier tape around a hub of a tape reel to form a coiled tape reel.

The computer server includes a first communication port and a second communication port. The first communication port is used for exchanging data with a control unit of the automated reel changer. The second communication port is used for exchanging data with a user computing device, such a computing laptop or a handphone.

A user can send commands from the computing device to the control unit of the automated reel changer via the computer server. In one example of this arrangement, the user sends commands for performing remote diagnostic of the tape and reel unit.

The control unit can also send an alert using email (electronic email) or messages such as SMS (Short Messaging System to the user via the computer server.

The first communication port and/or the second communication port can include a wireless communication module for providing a wireless means for transferring data.

The first communication port and/or the second communication port can also include a wired communication module for providing a wired means for transferring data.

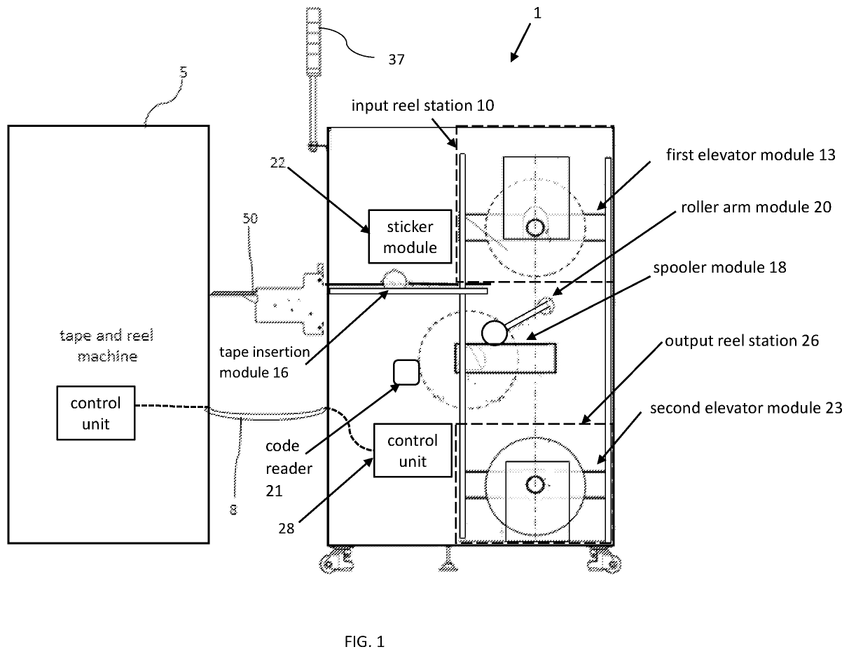

FIG. 1 illustrates a diagram of an improved automated output reel changer that is connected to a tape and reel machine,

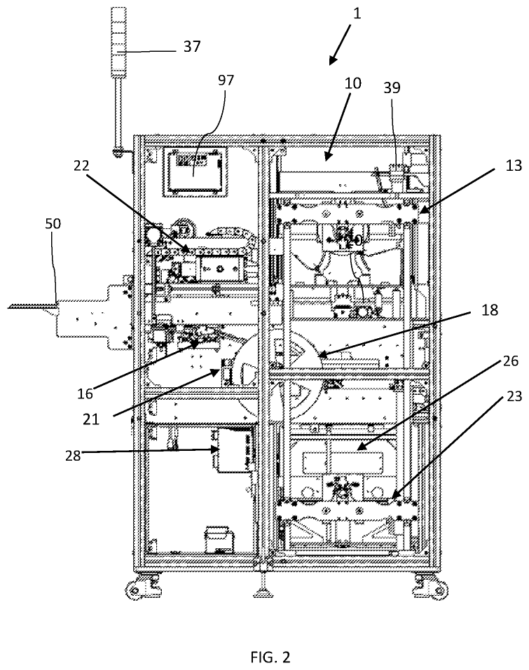

FIG. 2 illustrates a rear view of the improved automated output reel changer of FIG. 1 without housing covers of the improved automated output reel changer,

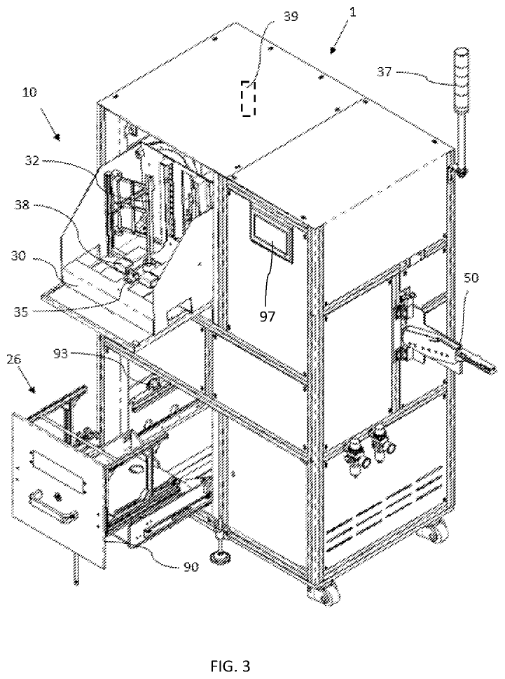

FIG. 3 illustrates a perspective view of an input reel station and an output reel station of the improved automated output reel changer of FIG. 1,

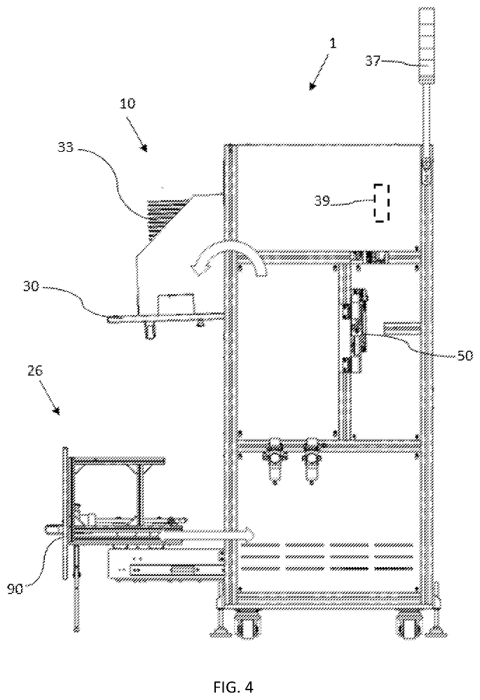

FIG. 4 illustrates a side view of the input reel station and the output reel station of FIG. 3,

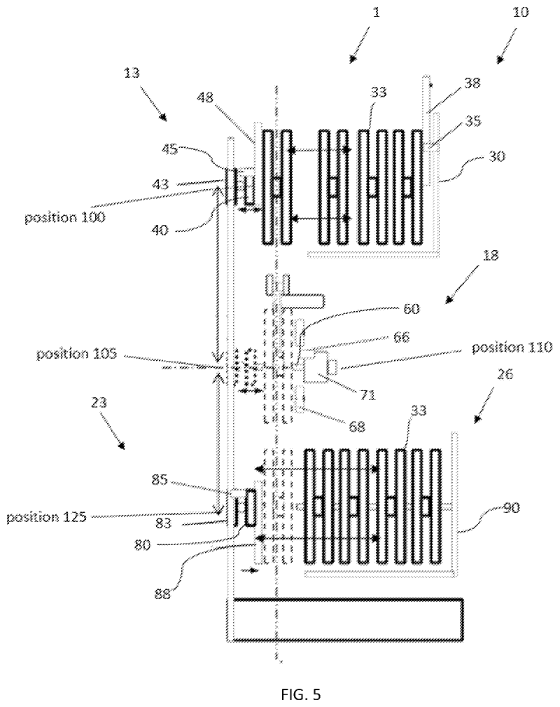

FIG. 5 illustrates a side schematic view of the improved automated output reel changer of FIG. 1,

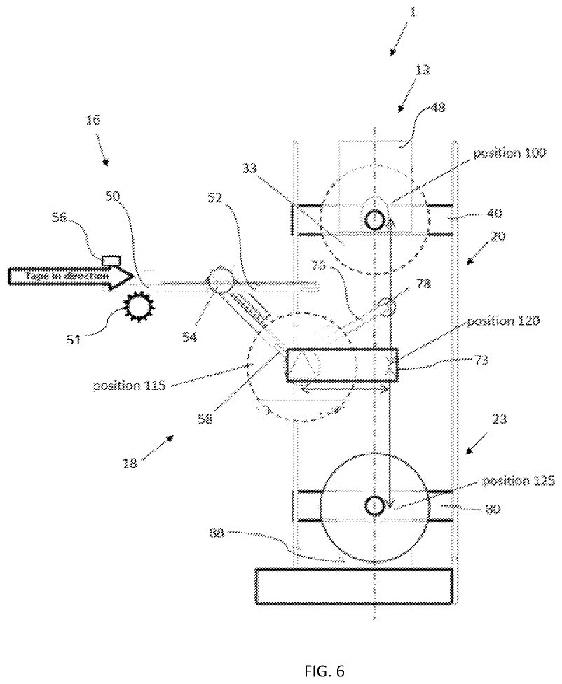

FIG. 6 illustrates a front schematic view of the improved automated output reel changer of FIG. 5,

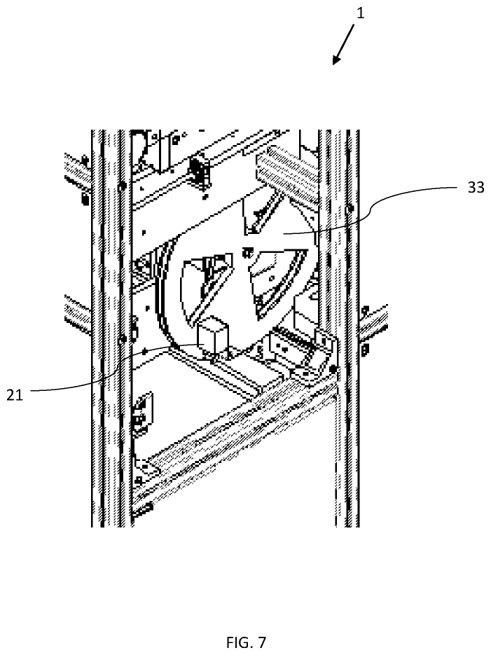

FIG. 7 illustrate a perspective view of a bar code scanner module of the improved automated output reel changer of FIG. 1, wherein the bar code scanner module is placed next to a tape reel,

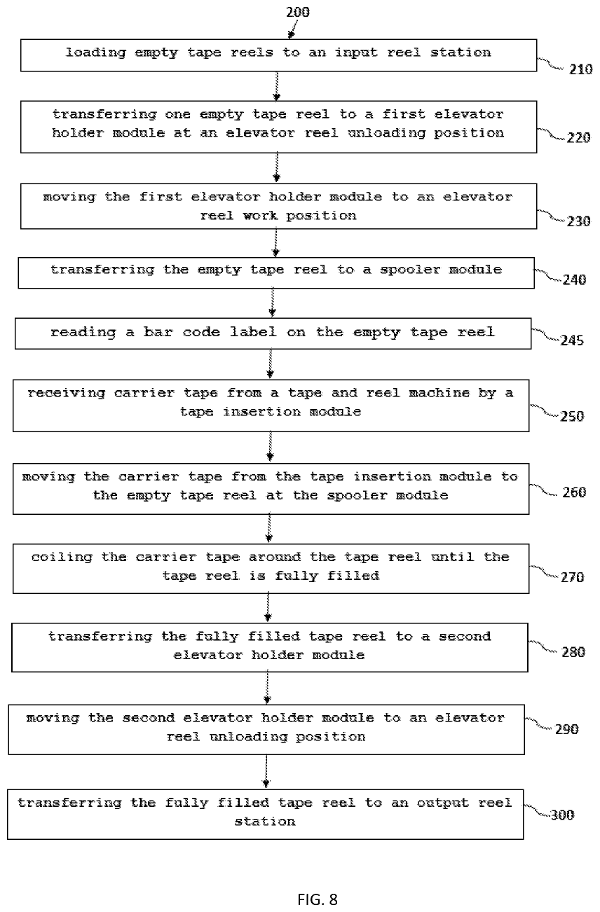

FIG. 8 illustrates a flow chart of a method for operating the improved automated output reel changer of FIG. 1,

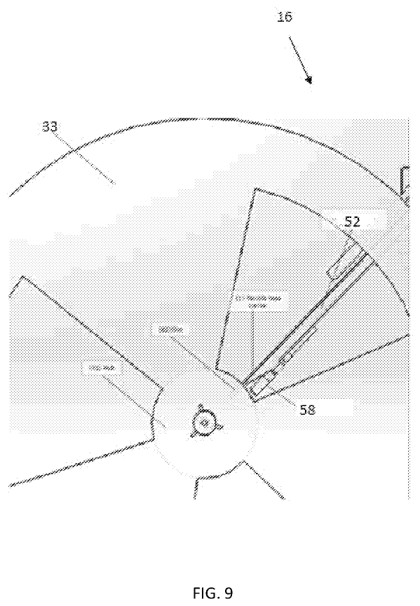

FIG. 9 illustrates a part of a tape insertion module of the improved automated output reel changer of FIG. 1,

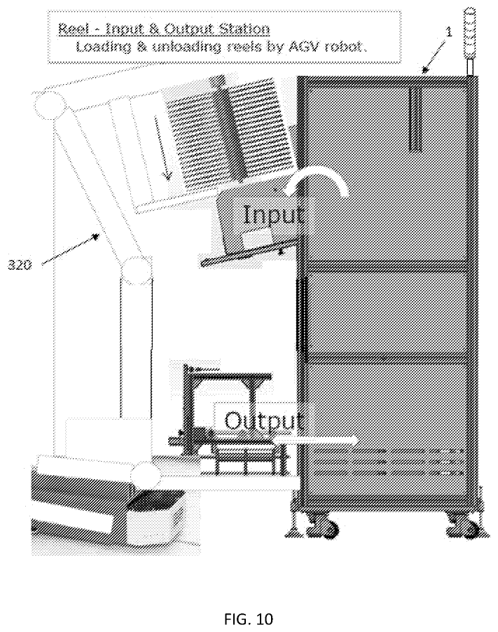

FIG. 10 illustrates another embodiment of the improved automated output reel changer of FIG. 1,

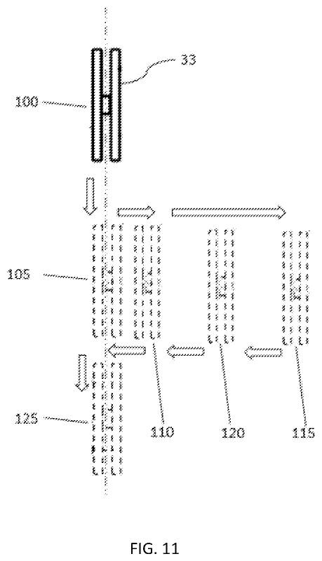

FIG. 11 illustrates various positions of a moving tape reel when operating the improved automated output reel changer of FIG. 1, and

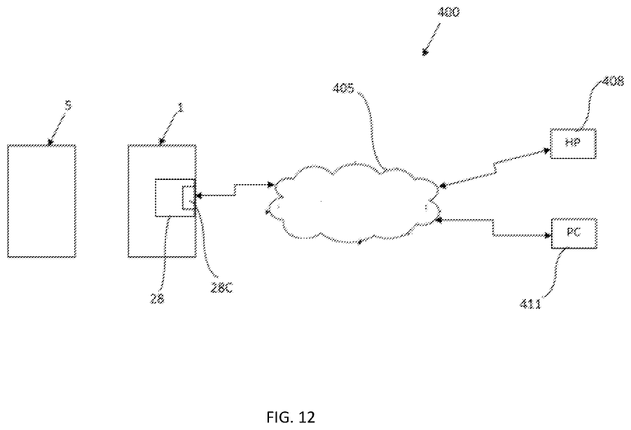

FIG. 12 illustrates an integrated system that includes the improved automated output reel changer and the tape and reel machine of FIG. 1.

In the following description, details are provided to describe embodiments of the application. It shall be apparent to one skilled in the art, however, that the embodiments may be practiced without such details.

Some parts of the embodiment have similar parts. The similar parts may have the same names or similar part numbers. The description of one similar part also applies by reference to another similar part, where appropriate, thereby reducing repetition of text without limiting the disclosure.

FIGS. 1 and 2 show an improved automated output reel changer 1, which is mechanically connected to a tape and reel machine 5. The improved automated output reel changer 1 is also electrically connected to the tape and reel machine 5 through electrical wires 8.

The automated output reel changer 1 includes an input reel station 10, a first elevator holder module 13, a tape insertion module 16, a spooler module 18 with a roller arm module 20, with a bar code scanner module 21, and with a sticker module 22, a second elevator holder module 23, and an output reel station 26 as well as a control unit 28. The bar code scanner module 21 is also called a code reader.

The input reel station 10 is located next to the first elevator holder module 13, which is located next to the spooler module 18. The spooler module 18 is located next to the roller arm module 20 and next to the tape insertion module 16. The spooler module 18 is also located next to the bar code scanner module 21 and next to the sticker module 22. The spooler module 18 is also located next to the second elevator holder module 23, which is located next to the output reel station 26. The control unit 28 is electrically connected to the input reel station 10, to the first elevator holder module 13, to the tape insertion module 16, to the spooler module 18, to the roller arm module 20, and to the second elevator holder module 23. The control unit 28 is also communicatively connected to a control unit of the tape and reel machine 5.

As better seen in FIGS. 3 and 4, the input reel station 10 comprises an empty reel swing drawer 30, a drawer spindle shaft 32, a drawer reel presence sensor 35, a drawer tape reel linear actuator 38, and a tape reel stopper 39.

The drawer spindle shaft 32 and the drawer reel presence sensor 35 are placed inside the swing drawer 30. The drawer reel presence sensor 35 and the drawer tape reel linear actuator 38 are electrically connected to the control unit 28. When the empty reel swing drawer 30 is placed in a drawer closed position, the tape reel stopper 39 is located near a distal end of the drawer spindle shaft 32 and the distal end of the drawer spindle shaft 32 is located between a proximal end of the drawer spindle shaft 32 and the position of the tape reel stopper 39.

The spindle shaft 32 has a length that is sized to receive multiple tape reels 33 in a stack.

The spindle shaft can be sized to receive 20 pieces of tape reels, which are adapted for carrying 8 mm (millimeter) carrier tape. In other words, the carrier tape has a width of 8 mm.

Alternatively, the spindle shaft can also be sized to receive 15 pieces of tape reels, which are adapted for carrying 12 mm carrier tape.

The tape reel stopper 39 includes an air cylinder and a movable stopper element, which is connected to the air cylinder. The air cylinder is electrically connected to the control unit 28.

In another embodiment, the spindle shaft is sized to receive 10 pieces of tape reels, which are adapted for carrying 16 mm carrier tape.

Referring to FIGS. 5 and 6, the first elevator holder module 13 includes a first vertically movable elevator reel holder 40, a first elevator reel holder linear actuator 43, a first elevator reel presence sensor 45, and a first elevator tape reel linear actuator 48.

The first elevator reel holder linear actuator 43 is connected to the first vertically movable elevator reel holder 40 and it is electrically connected to the control unit 28.

The first elevator reel presence sensor 45 is electrically connected to the control unit 28 and it is placed near to the first elevator reel holder 40.

The first elevator tape reel linear actuator 48 is also electrically connected to the control unit 28.

Referring to the tape insertion module 16, it comprises an incoming tape guide track 50 with a tape indexer 51, a rotatable tape insertion guide track 52 with a rotating shaft, an insertion guide track rotary actuator 54, a tape presence sensor 56, and a reel slot detection sensor 58. The tape indexer 51 includes a sprocket wheel.

One end of the rotatable tape insertion guide track 52 is positioned next to one end of the incoming tape guide track 50.

The incoming tape guide track 50 is placed above the tape indexer 51, which is electrically connected to the control unit 28.

The insertion guide track rotary actuator 54 is electrically connected to the control unit 28. The insertion guide track rotary actuator 54 is also connected to the rotatable tape insertion guide track 52.

The tape presence sensor 56 is electrically connected to the control unit 28 and it is located next to the incoming tape guide track 50.

The reel slot detection sensor 58 is electrically connected to the control unit 28 and it is located at a distal end of the rotatable tape insertion guide track 52.

Referring to the spooler module 18, it includes a spooler reel holder 60, a spooler motor 71, a spooler motor linear actuator 73, a spooler reel presence sensor 66, and a spooler tape reel linear actuator 68.

The spooler reel holder 60 is connected to the spooler motor 71. The spooler motor 71 is also connected to the spooler motor linear actuator 73. Both the spooler motor 71 and the spooler motor linear actuator 73 are electrically connected to the control unit 28. The spooler motor 71 includes a sprocket wheel for engaging with sprocket openings of a carrier tape. The spooler motor linear actuator 73 is configured to move the spooler motor 71 with the spooler reel holder 60 horizontally.

The spooler reel presence sensor 66 is electrically connected to the control unit 28 and it is located next to the spooler reel holder 60. The spooler tape reel linear actuator 68 is also electrically connected to the control unit 28.

The roller arm module 20 includes a roller arm 76 and a roller arm rotary actuator 78. The roller arm rotary actuator 78 is connected to the roller arm 76 and it is electrically connected to the control unit 28.

Referring to the bar code scanner module 21, it is configured to retrieve information from a one-dimensional (1D) bar code label or from a two-dimensional (2D) bar code label, which is provided on a surface of a tape reel 33, as shown in FIG. 7. The bar code scanner module 21 then sends the retrieved information to the control unit 28. In one implementation, the bar code scanner module 21 is configured to read or detect a bar code label that has a rectangular area of not more than 37 millimeter (mm) by 57 mm and that is placed within about 90 mm to 100 mm from the bar code scanner module 21.

Referring to the second elevator holder module 23, it includes a second vertically movable elevator reel holder 80, a second elevator reel holder linear actuator 83, a second elevator reel presence sensor 85, and a second elevator tape reel linear actuator 88.

The second elevator reel holder linear actuator 83 is connected to the second vertically movable elevator reel holder 80 and it is electrically connected to the control unit 28.

The second elevator reel presence sensor 85 is electrically connected to the control unit 28 and it is placed near to the second elevator reel holder 80.

The second elevator tape reel linear actuator 88 is also electrically connected to the control unit 28.

Referring to the output reel station 26, it includes a drawer 90 and a drawer reel presence sensor 93. The drawer reel presence sensor 93 is placed near to the drawer 90. The drawer reel presence sensor 93 is electrically connected to the control unit 28.

The automated output reel changer 1 further includes a machine status indicator light unit 37, which is electrically connected to the control unit 28. The machine status indicator light unit 37 includes a plurality of light sources for emitting different colour lights.

The automated output reel changer 1 also includes a human machine interface (HMI) panel 97, which is shown in FIGS. 2 and 3. The HMI interface 97 is electrically connected to the control unit 28. The HMI panel 97 includes a display for displaying, for example, machine status and for receiving instructions from a user.

FIG. 8 shows a flow chart 200 of a method for operating the improved automated output reel changer 1.

The method includes a step 210 of loading a plurality of empty tape reels 33 to the input reel station 10. In detail, a user opening the swing drawer 30 of the input reel station 10 to place the swing drawer 30 in a drawer open position, wherein the drawer spindle shaft 32 of the swing drawer 30 essentially extends vertically.

The user later places a plurality of empty tape reels 33 in the swing drawer 30 such that the empty tape reels 33 are essentially in a vertical stack and that the drawer spindle shaft 32 essentially extends vertically through the central openings of the hubs of the empty tape reels 33.

The user later places the swing drawer 30 of the input reel station 10 in a drawer closed position, wherein the empty tape reels 33 are essentially in a horizontal stack and the drawer spindle shaft 32 essentially extends horizontally through the central openings of the hubs of the empty tape reels 33. The empty tape reels 33 are placed next to the tape reel stopper 39, wherein the stopper element of the tape reel stopper 39 acts to touch and stop the empty tape reels 33 from moving away from the drawer spindle shaft 32.

The drawer reel presence sensor 35 of the input reel station 10 then detects a presence of the empty tape reels 33, which are loaded or placed inside the swing drawer 30, and it later sends a signal about the presence of the empty tape reels 33 to the control unit 28.

In a next step 220, one of the empty tape reels 33 is transferred to the first elevator holder module 13. In detail, the air cylinder of the tape reel stopper 39 is activated by the control unit 28 to move the stopper element away from the empty tape reels 33 in a direction that is essentially parallel to a major surface of the empty tape reel 33. The first elevator reel holder linear actuator 43 of the first elevator holder module 13 is then activated by the control unit 28 to move the first elevator reel holder 40 of the first elevator holder module 13 essentially in the vertical direction to a predetermined elevator reel loading position 100, which is better seen in FIG. 11. At this position, the first elevator reel holder 40 is placed next to the empty tape reels 33, which are located in the swing drawer 30.

After this, the drawer tape reel linear actuator 38 of the input reel station 10 is activated by the control unit 28 to push the empty tape reels 33 in the swing drawer 30 essentially in the horizontal direction towards the first elevator reel holder 40 of the first elevator holder module 13.

The first elevator reel holder 40 later receives one tape reel of the empty tape reels 33, which is placed adjacent to the first elevator reel holder 40.

The first elevator reel presence sensor 45 of the first elevator holder module 13 later detects a presence of the tape reel 33 in the first elevator reel holder 40 and it afterward sends a signal about the presence of the tape reel 33 to the control unit 28.

In a subsequent step 230 of moving the first elevator holder module 13 to a predetermined elevator reel work position 105. In detail, the first elevator reel holder linear actuator 43 of the first elevator holder module 13 is activated by the control unit 28 to move the first elevator reel holder 40 with the received empty tape reel 33 essentially in the downward vertical direction to place the first elevator reel holder 40 at the predetermined elevator reel work position 105.

Referring to the spooler module 18, after this, the spooler motor linear actuator 73 of the spooler module 18 is activated by the control unit 28 to move the spooler reel holder 60 of the spooler module 18 to a predetermined spooler reel holder standby position 110, which is located next to the predetermined elevator reel work position 105.

The first elevator tape reel linear actuator 48 is then activated by the control unit 28 to push the empty tape reel 33 in the first elevator reel holder 40 of the first elevator holder module 13 towards the spooler reel holder 60 of the spooler module 18.

The spooler reel holder 60 of the spooler module 18 afterward receives the empty tape reel 33 from the first elevator reel holder 40, in a step 240.

The spooler reel presence sensor 66 of the spooler module 18 later detects a presence of the empty tape reel 33 in the spooler reel holder 60 of the spooler module 18, and it sends a signal about the presence of the empty tape reel 33 to the control unit 28.

The scanner module 21 also reads or senses a bar code label that is provided on a surface of the tape reel 33, in a step 245. The bar code label contains information about the tape reel 33, which can be used for inventory control and component traceability.

The spooler motor linear actuator 73 of the spooler module 18 is then activated by the control unit 28 to move the spooler reel holder 60 with the empty tape reel 33 essentially in the horizontal direction from the predetermined spooler reel holder standby position 110 to a predetermined spooler tape receiving position 115.

The first elevator reel holder linear actuator 43 of the first elevator holder module 13 is then activated by the control unit 28 to move the first elevator reel holder 40 in the upward vertical direction to move the first elevator reel holder 40 to the predetermined elevator reel loading position 100 from the predetermined elevator reel work position 105.

Referring to the tape and reel machine, it later moves a flexible carrier tape with a predetermined length, in a step 260, wherein a sprocket wheel of the tape and reel machine engages with sprocket openings or with indexing holes of the carrier tape in order to move the carrier tape. The carrier tape includes pockets, which contain semiconductor die, wherein the pockets are sealed with a cover tape.

With respect to the tape insertion module 16, a leading end portion of the carrier tape then shifts to the incoming tape guide track 50. The sprocket wheel of the tape indexer 51 afterward engages with indexing holes of the carrier tape to move the carrier tape to the rotatable tape insertion guide track 52 of the tape insertion module 16.

The leading end portion of the moving carrier tape later reaches a distal end of the tape insertion guide track 52.

The tape presence sensor 56 of the tape insertion module 16 later detects a presence of the carrier tape leading end portion at the distal end of the tape insertion guide track 52 and it afterward sends a signal about this presence of the carrier tape to the control unit 28.

The control unit 28 subsequently sends a stop signal to the tape and reel machine, wherein the tape and reel machine then stops moving the carrier tape.

The insertion guide track rotary actuator 54 of the tape insertion module 16 is later activated by the control unit 28 to rotate the distal end of the tape insertion guide track 52 with the leading end portion of the carrier tape about its rotating shaft by a predetermined angle of about 45 degrees.

The spooler motor 71 of the spooler module 18 is later activated by the control unit 28 to rotate the tape reel 33. When the reel slot detection sensor 58 of the tape insertion module 16 detects a presence of the slot of the hub of the empty reel at a predetermined reel angular position, as shown in FIG. 9, later sends a signal about the presence of the slot of the hub of the empty tape reel 33 to the control unit 28. The control unit 28 later sends a signal to the spooler motor 71 to stop rotating the tape reel 33.

The control unit 28 later sends a start signal to the tape and reel machine, wherein the tape and reel machine then resumes moving the carrier tape.

The leading end portion of the moving carrier tape is then moved and is inserted into the slot of the hub of the tape reel 33.

With respect to the roller arm module 20, the rotary actuator of the roller arm module 20 is then activated by the control unit 28 to rotate the roller arm 76 from a predetermined roller arm standby position to a predetermined roller arm work position, wherein a distal end of the roller arm 76 presses a part of the carrier tape, which is located near to the slot of the hub of the tape reel 33.

The pressing of the roller arm 76 onto the carrier tape acts to press a part of the carrier tape onto the slot of the hub of the empty tape reel 33 such that the hub grips the carrier tape by frictional forces. In other words, this pressing prevents the carrier tape from being loose. This is useful, especially during a later coiling of the carrier tape.

The spooler motor linear actuator 73 is later activated by the control unit 28 to move the spooler motor 71 essentially in the horizontal direction from the predetermined spooler tape receiving position 115 to a predetermined spooler tape coiling position 120, wherein the spooler motor 71 engages with the tape reel 33, which is placed in the reel holder of the spooler module 18.

The spooler motor 71 is later activated by the control unit 28 to rotate the tape reel 33, wherein the rotation of the tape reel 33 acts to coil the carrier tape around the hub of the tape reel 33, in a step 270. The sprocket wheel of the tape indexer 51 afterward disengages with indexing holes of the carrier tape.

When the predetermined length of the carrier tape is wound around the tape reel 33, the tape reel 33 is full, and the tape presence sensor 56 of the tape insertion module 16 stops detecting the presence of the carrier tape at the distal end of the tape insertion guide track 52 and it afterward sends a signal about this absence of the carrier tape to the control unit 28.

The spooler motor 71 is then activated by the control unit 28 to stop rotating the tape reel 33.

The sticker module 22 later places a sticker onto a trailing end portion of the carrier tape, which is being wound around the hub of the tape reel 33. The sticker acts to adhere or stick the trailing end portion onto a part of the carrier tape such that the carrier tape remains being coiled around the tape reel 33. In other words, the carrier tape is not in a loose form.

The rotary actuator of the roller arm module 20 is afterward activated by the control unit 28 to rotate the roller arm 76 from the predetermined roller arm work position to the predetermined roller arm standby position.

The spooler motor linear actuator 73 of the spooler module 18 is then activated by the control unit 28 to move the spooler reel holder 60 of the spooler module 18 with the full tape reel 33 essentially in the horizontal direction from the predetermined spooler tape coiling position 120 to the predetermined spooler reel holder standby position 110.

Referring to the second elevator holder module 23, the second elevator reel holder linear actuator 83 is then activated by the control unit 28 to move the second elevator reel holder 80 of the second elevator holder module 23 to the predetermined elevator reel work position 105, which next to the predetermined spooler reel holder standby position 110.

The spooler tape reel linear actuator 68 is then activated by the control unit 28 to push the full tape reel 33 in the spooler reel holder 60 of the spooler module 18 towards the second elevator reel holder 80 of the second elevator holder module 23.

The second elevator reel holder 80 of the second elevator holder module 23 afterward receives the full tape reel 33 from the spooler reel holder 60 of the spooler module 18, in a step 280.

The second elevator reel presence sensor 85 of the second elevator holder module then detects a presence of the full tape reel 33 in the second elevator reel holder 80 of the second elevator holder module, and it sends a signal about the presence of the full tape reel 33 to the control unit 28.

The second elevator reel holder linear actuator 83 of the second elevator module is then activated by the control unit 28 to move vertically downwards the second elevator reel holder 80 from the predetermined elevator reel work position 105 to a predetermined elevator reel unloading position 125, in a step 290.

In a subsequent step 300, the second elevator tape reel linear actuator 88 of the second elevator holder module is activated by the control unit 28 to push the full tape reel 33 in the second elevator reel holder 80 to a drawer 90 of the output reel station 26.

When the drawer reel presence sensor 93 detects that the drawer 90 is filled with a predetermined number or fully filled with the full tape reels 33, the drawer reel presence sensor 93 sends a detection signal to the control unit 28. The control unit 28 later activates the machine status indicator light unit 37 to emit, for example, red light to alert the user to remove these full tape reels 33.

The user can then also place empty tape reels 33 in the swing drawer 30 of the input reel station 10.

In another embodiment, the automated output reel changer 1 is adapted to work cooperatively with an automated guided vehicle (AGV), as illustrated in FIG. 10. The automated guided vehicle refers to a movable robot that uses, for an example, computer vision for navigation. The automated guided vehicle can then load multiple empty tape reels into the swing drawer 30 of the input reel station 10 as well as removing full tape reels from the drawer 90 of the output reel station 26.

FIG. 12 shows an integrated system 400. The integrated system 400 includes the automated output reel changer 1 and the tape and reel machine 5 of FIG. 1.

The output reel changer 1 includes the control unit 28 with a communication port 28C. The communication port 28C is communicatively connected to a cloud computing system 405 by a wireless means 406, such as Wifi.

The cloud computing system 405 is also communicatively connected to a user mobile device 408, such as mobile phone and a user computing device 411, such as a laptop or a desktop computer.

The cloud computing system 405 comprises one or more computers.

In a general sense, the communication port 28C can also be communicatively connected to the cloud computing system 405 by a wired means, such as Ethernet cables.

In use, the communication port 28C allows transfer of information between the control unit 28 and the cloud computing system 405.

The cloud computing system 405 also enable transfer of information between the control unit 28 and the user mobile device 408 as well as transfer of information between the control unit 28 and the user computing device 411.

A software application of the user mobile device 408 and/or the user computing device 411 allows a user to view reports or data from the output reel changer 1. The data can be in the form of a table or a graph, which can be exported in the Microsoft Excel format.

The software application also allows the user to send commands or instructions to the output reel changer 1. In one example, the software application enables the user to perform remote diagnostic of the integrated system 400.

The software application can also send an alert using email (electronic email) or messages such as SMS (Short Messaging System.

The embodiments can also be described with the following lists of features or elements being organized into an item list. The respective combinations of features, which are disclosed in the item list, are regarded as independent subject matter, respectively, that can also be combined with other features of the application.

1. An automated reel changer for a tape and reel machine, the automated reel changer comprising
an input reel station for receiving a plurality of tape reels,
a movable first elevator holder module for receiving the plurality of tape reels from the input reel station and for moving the tape reels essentially downwards to an elevator reel work position,
a movable spooler module for receiving the tape reel at the elevator reel work position from the first elevator holder module,
a tape insertion module for receiving a carrier tape from the tape and reel machine and for guiding the carrier tape, wherein the spooler module is further provided for positioning the tape reel to receive the carrier tape from the tape and reel machine, and for coiling the carrier tape around a hub of the tape reel to form a coiled tape reel,
a movable second elevator holder module for receiving the coiled tape reel from the spooler module and for moving the coiled tape reel essentially downwards to an elevator reel unloading position,
an output reel station for receiving the coiled tape reel from the second elevator holder module, and
a control unit, wherein the control unit is adapted to direct movement of the first elevator holder module, movement of the spooler module, movement of the tape insertion module, and movement of the second elevator holder module.

2. The automated reel changer according to item 1 further comprising a sticker module for placing a sticker onto an end portion of the carrier tape that is provided for coiling around the hub of the tape reel.

3. The automated reel changer according to item 1 or 2 further comprising a bar code scanner for retrieving information from a bar code label of the tape reel regarding the tape reel.

4. The automated reel changer according to one of items 1 to 3, wherein the control unit comprises a port for communicating with a computer server.

5. The automated reel changer according to one of items 1 to 4 further comprising a roller arm module for pressing the moving carrier tape that is provided for coiling around the hub of the tape reel.

6. A tape and reel unit comprising a tape and reel machine, an automated reel changer of one of items 1 to 5 for receiving a carrier tape from the tape and reel machine and for coiling the carrier tape around a hub of a tape reel to form a coiled tape reel, and an automated guided vehicle (AGV) for transporting the coiled tape reel from the automated reel changer to a pre-determined location.

7. The tape and reel unit according to item 6, wherein the automated guided vehicle (AGV) is further adapted for transporting a plurality of tape reels to the automated reel changer.

8. A tape and reel unit comprising a tape and reel machine, an automated reel changer of one of items 1 to 5 for receiving a carrier tape from the tape and reel machine and for coiling the carrier tape around a hub of a tape reel to form a coiled tape reel, and a computer server comprising a first communication port for exchanging data with a control unit of the automated reel changer and a second communication port for exchanging data with a user computing device.

9. The tape and reel unit according to item 8, wherein the first communication port and/or the second communication port comprises a wireless communication module.

10. The tape and reel unit according to item 8 or 9, wherein the first communication port and/or the second communication port comprises a wired communication module.

Although the above description contains much specificity, this should not be construed as limiting the scope of the embodiments but merely providing illustration of the foreseeable embodiments. The above-stated advantages of the embodiments should not be construed especially as limiting the scope of the embodiments but merely to explain possible achievements if the described embodiments are put into practice. Thus, the scope of the embodiments should be determined by the claims and their equivalents, rather than by the examples given.

### REFERENCE NUMBERS

1 improved automated output reel changer
5 tape and reel machine
8 electrical wires
10 input reel station
13 first elevator holder module
16 tape insertion module
18 spooler module
20 roller arm module
21 bar code scanner module
22 sticker module
23 second elevator holder module
26 output reel station
28 control unit
28C communication port
30 empty reel swing drawer
32 drawer spindle shaft
33 tape reel
35 drawer reel presence sensor
37 machine status indicator light unit
38 drawer tape reel linear actuator
39 tape reel stopper
40 first elevator reel holder
43 first elevator reel holder linear actuator
45 first elevator reel presence sensor
48 first elevator tape reel linear actuator
50 incoming tape guide track
51 tape indexer
52 rotatable tape insertion guide track
54 insertion guide track rotary actuator
56 tape presence sensor
58 reel slot detection sensor
60 spooler reel holder
66 spooler reel presence sensor
68 spooler tape reel linear actuator
71 spooler motor
73 spooler motor linear actuator
76 roller arm
78 roller arm rotary actuator
80 second elevator reel holder
83 second elevator reel holder linear actuator
85 second elevator reel presence sensor
88 second elevator tape reel linear actuator
90 drawer
93 drawer reel presence sensor
97 HMI interface
100 elevator reel loading position
105 elevator reel work position
110 spooler reel holder standby position
115 spooler tape receiving position
120 spooler tape coiling position
125 elevator reel unloading position
200 flow chart
210 step
220 step
230 step
240 step
245 step
250 step
260 step
270 step
280 step
290 step
300 step
320 automated guided vehicle
400 integrated system
406 wireless means
408 mobile device
411 computing device

1. An automated reel changer for a tape and reel machine, the automated reel changer comprising
an input reel station for receiving a plurality of tape reels,
a movable first elevator holder module for receiving the plurality of tape reels from the input reel station and for moving the tape reels essentially downwards to an elevator reel work position,
a movable spooler module for receiving the tape reel at the elevator reel work position from the first elevator holder module,
a tape insertion module for receiving a carrier tape from the tape and reel machine and for guiding the carrier tape,
wherein the spooler module is further provided for positioning the tape reel to receive the carrier tape from the tape and reel machine, and for coiling the carrier tape around a hub of the tape reel to form a coiled tape reel,
a movable second elevator holder module for receiving the coiled tape reel from the spooler module and for moving the coiled tape reel essentially downwards to an elevator reel unloading position,
an output reel station for receiving the coiled tape reel from the second elevator holder module, and
a control unit,
wherein the control unit is adapted to direct movement of the first elevator holder module, movement of the spooler module, movement of the tape insertion module, and movement of the second elevator holder module.

2. The automated reel changer according to claim 1 further comprising
a sticker module for placing a sticker onto an end portion of the carrier tape that is provided for coiling around the hub of the tape reel.

3. The automated reel changer according to claim 1 further comprising
a bar code scanner for retrieving information from a bar code label of the tape reel regarding the tape reel.

4. The automated reel changer according to claim 1, wherein the control unit comprises a port for communicating with a computer server.

5. The automated reel changer according to claim 1 further comprising
a roller arm module for pressing the moving carrier tape that is provided for coiling around the hub of the tape reel.

6. A tape and reel unit comprising
a tape and reel machine,
an automated reel changer of claim 1 for receiving a carrier tape from the tape and reel machine and for coiling the carrier tape around a hub of a tape reel to form a coiled tape reel, and
an automated guided vehicle (AGV) for transporting the coiled tape reel from the automated reel changer to a pre-determined location.

7. The tape and reel unit according to claim 6, wherein
the automated guided vehicle (AGV) is further adapted for transporting a plurality of tape reels to the automated reel changer.

8. A tape and reel unit comprising
a tape and reel machine,
an automated reel changer of claim 1 for receiving a carrier tape from the tape and reel machine and for coiling the carrier tape around a hub of a tape reel to form a coiled tape reel, and
a computer server comprising a first communication port for exchanging data with a control unit of the automated reel changer and a second communication port for exchanging data with a user computing device.

9. The tape and reel unit according to claim 8, wherein the first communication port and/or the second communication port comprises a wireless communication module.

10. The tape and reel unit according to claim 8, wherein the first communication port and/or the second communication port comprises a wired communication module.
